(19) United States
(12) Patent Application Publication
(10) Pub. No.: US 2025/0336881 A1
(43) Pub. Date: Oct. 30, 2025

(54) METHOD FOR MANUFACTURING SEMICONDUCTOR DEVICE

(71) Applicant: Resonac Corporation, Minato-ku, Tokyo (JP)

(72) Inventors: Toshiaki SHIRASAKA, Minato-ku, Tokyo (JP); Tomoaki SHIBATA, Minato-ku, Tokyo (JP); Shizu FUKUZUMI, Minato-ku, Tokyo (JP); Tadashi OKUDA, Minato-ku, Tokyo (JP)

(21) Appl. No.: 18/861,215

(22) PCT Filed: May 23, 2023
(86) PCT No.: PCT/JP2023/019135

§ 371 Date: Oct. 29, 2024

(30) Foreign Application Priority Data
May 25, 2022 (WO) PCT/JP2022/021410

(51) Int. Cl. H01L 23/00

(52) U.S. Cl. CPC H01L 24/80; H01L 2224/80047; H01L 2224/80203; H01L 2224/80895; H01L 2224/80896

(57) ABSTRACT

A method for manufacturing a semiconductor device includes preparing first and second semiconductor substrates, dividing the second semiconductor substrate into semiconductor chips, and bonding the first organic insulating layer and an insulating layer portion of the semiconductor chip to each other and bonding the first electrode and the second electrode to each other by heating and pressurizing them. Before heating, at least one of a first protrusion amount of the first electrode or a second protrusion amount of the second electrode is a protrusion amount within 130% of a protrusion amount ΔL represented by Formula (1). In Formula (1), D is a layer thickness of the organic insulating layer, ΔT is a temperature difference of a heating temperature, α1 is the linear expansion coefficient of the organic insulating layer, and α2 is the linear expansion coefficient of the electrode.

$$\begin{matrix}[ Formula 1 ] & \\ Δ L = \frac{D \times Δ T \times ( α 1 - α 2 )}{1 + Δ T \times α 2} & ( 1 )\end{matrix}$$

### TECHNICAL FIELD

The present disclosure relates to a method for manufacturing a semiconductor device.

### BACKGROUND ART

In recent years, three-dimensional mounting has been studied to improve the degree of integration of LSIs. Non Patent Literature 1 discloses an example of three-dimensional mounting of semiconductor chips.

### CITATION LIST

### Non Patent Literature

Non Patent Literature 1: F. C. Chen et al., “System on Integrated Chips (SoIC™) for 3D Heterogeneous Integration”, 2019 IEEE 69th Electronic Components and Technology Conference (ECTC), p. 594-599 (2019)

### SUMMARY OF INVENTION

### Technical Problem

In the case of three-dimensional mounting of semiconductor chips, use of a hybrid bonding technique for wafer-to-wafer (W2 W) bonding has been studied in order to miniaturize wiring. In this case, unlike the W2 W process, a chip-on-wafer (CoW) process is used, and singulation into semiconductor chips is performed. Dicing at the time of singulation may cause debris (cut fragments). When debris adheres to a bonding interface (insulating layer of hybrid bonding) of a semiconductor chip or the like, a bonding failure may occur in a semiconductor device that is produced. Therefore, use of an organic insulating material for the insulating layer at the bonding interface has been studied so as to absorb debris. However, the organic insulating material has a linear expansion coefficient different from that of a metal material used for electrodes, and thus the organic insulating material may expand more than the metal material due to heating at the time of bonding, and may inhibit bonding between the electrodes.

An object of the present disclosure is to provide a method for manufacturing a semiconductor device capable of improving bonding between electrodes in a hybrid bonding method using an organic insulating layer.

### Solution to Problem

A method for manufacturing a semiconductor device according to one aspect of the present disclosure includes, preparing a first semiconductor substrate including a first substrate main body, and a first organic insulating layer and a first electrode which are provided on a surface of the first substrate main body; preparing a second semiconductor substrate including a second substrate main body, and a second organic insulating layer and a plurality of second electrodes which are provided on a surface of the second substrate main body; dividing the second semiconductor substrate to obtain a plurality of semiconductor chips each including an insulating layer portion corresponding to the second organic insulating layer and at least one second electrode; aligning a second electrode of at least one semiconductor chip among the plurality of semiconductor chips with respect to the first electrode of the first semiconductor substrate; and bonding the first organic insulating layer and the insulating layer portion to each other, and bonding the first electrode and the second electrode to each other, by heating and pressurizing the first semiconductor substrate and the semiconductor chip. In the method for manufacturing the semiconductor device, before heating the first semiconductor substrate and the semiconductor chip, at least one of a first protrusion amount or a second protrusion amount is a protrusion amount within 130% of a protrusion amount ΔL represented by Formula (1) below. The first protrusion amount is an amount by which the first electrode protrudes from the surface of the first organic insulating layer and the second protrusion amount is an amount by which the second electrode protrudes from the surface of the second organic insulating layer or the insulating layer portion.

$$\begin{matrix}[ Formula 1 ] & \\ Δ L = \frac{D \times Δ T \times ( α 1 - α 2 )}{1 + Δ T \times α 2} & ( 1 )\end{matrix}$$

In the above formula, D is a layer thickness of the first organic insulating layer or a layer thickness of the second organic insulating layer, ΔT is a temperature difference between the temperature before the bonding and the heating temperature at the time of the bonding, α1 is a linear expansion coefficient of the material forming the first insulating layer or the second organic insulating layer, and α2 is a linear expansion coefficient of the material forming the first electrode or the second electrode.

In the method for manufacturing the semiconductor device, before heating the first semiconductor substrate and the semiconductor chip, at least one of the first protrusion amount by which the first electrode protrudes from the surface of the first organic insulating layer or the second protrusion amount by which the second electrode protrudes from the surface of the second organic insulating layer or the insulating layer portion is a protrusion amount within 130% of a protrusion amount ΔL represented by Formula (1) above. That is, at a stage before heating, either the first electrode or the second electrode protrudes from the surface of the organic insulating layer by a predetermined amount, and even if the organic insulating layer thermally expands at the time of heating, the organic insulating layer does not inhibit adhesion (bonding) between the electrodes. Therefore, according to this manufacturing method, the bonding between the first electrode and the second electrode can be improved.

The method for manufacturing a semiconductor device may further include, polishing surfaces of the first organic insulating layer and the first electrode which are disposed on the surface side of the first semiconductor substrate; and polishing surfaces of the second organic insulating layer and the second electrode which are disposed on the surface side of the second semiconductor substrate. The corresponding polishing may be performed such that at least one of the first protrusion amount or the second protrusion amount is a protrusion amount within 85% of the protrusion amount ΔL. Ideally, the protrusion amount of each electrode is the same as the protrusion amount ΔL calculated from Formula (1), but since the organic insulating layer has a lower elastic modulus at the time of heating than the electrode and can push the organic insulating layer with a load at the time of thermocompression bonding, the protrusion amount of the electrode is preferably smaller than the protrusion amount ΔL calculated from Formula (1). As a result, the bonding between the first electrode and the second electrode can be more reliably improved. On the other hand, in a case where at least one of the first protrusion amount or the second protrusion amount is less than 20% of the protrusion amount ΔL, contact between the electrodes may be hindered by thermal expansion of the organic insulating layer during heating, and bonding of the electrodes may be insufficient. Therefore, the corresponding polishing is preferably performed such that at least one of the first protrusion amount or the second protrusion amount is a protrusion amount of 20% or more of the protrusion amount ΔL. In this case, the bonding state between the electrodes can be made more suitable.

In this method for manufacturing the semiconductor device, in the polishing the first semiconductor substrate, the first semiconductor may be polished such that a surface roughness Ra of each of the surfaces of the first organic insulating layer and the first electrode is 1 nm or less. In the polishing the second semiconductor substrate, the second semiconductor substrate may be polished such that the surface roughness Ra of each of the surfaces of the second organic insulating layer and the second electrode is 1 nm or less. In this case, the surface roughness Ra of the organic insulating layer to be bonded is reduced, and thus the bonding strength between the first organic insulating layer and the insulating layer portion of the semiconductor chip can be increased when the semiconductor chip is bonded to the first semiconductor substrate. The surface roughness Ra used here is an arithmetic average roughness (Ra) defined in JIS B 0601-2001.

In this method for manufacturing the semiconductor device, a protrusion amount of at least one of the first protrusion amount or the second protrusion amount may be 40 nm to 100 nm. In this case, even if the organic insulating layer expands at the time of heating, the organic insulating layer does not hinder bonding between the electrodes, and bonding between the first electrode and the second electrode can be improved.

In this method for manufacturing the semiconductor device, a protrusion amount of at least one of the first protrusion amount or the second protrusion amount may be 80 nm or less. In this case, even if the organic insulating layer expands at the time of heating, the organic insulating layer does not hinder bonding between the electrodes, and bonding between the first electrode and the second electrode can be improved. In addition, the protrusion amounts of both the first protrusion amount and the second protrusion amount may be 60 nm to 80 nm. In this case, the organic insulating layers are more reliably bonded to each other, the electrodes are more reliably bonded to each other, and both the organic insulating layers and the electrodes can be more reliably bonded to each other.

In this method for manufacturing the semiconductor device, it is preferable that, before the first semiconductor substrate and the semiconductor chip are heated, both the first protrusion amount and the second protrusion amount be protrusion amounts within 60% of the protrusion amount ΔL. In this case, even if the organic insulating layer thermally expands at the time of heating, the organic insulating layer can reliably prevent from hindering the bonding between the electrodes, and the bonding between the first electrode and the second electrode can be more reliably improved.

In this method for manufacturing the semiconductor device, it is preferable that, in the thermally bonding the semiconductor chip to the first semiconductor substrate, heating be performed such that at least one of a first step difference amount between the first electrode and the first organic insulating layer or a second step difference amount between the second electrode and the second organic insulating layer is 10 nm or less. When the first semiconductor substrate and the semiconductor chip are heated and bonded, each organic insulating layer may thermally expand, but since the step between the electrode and the insulating layer when expanded is 10 nm or less, it is possible to more reliably prevent the organic insulating layer from inhibiting the bonding between the electrodes. As a result, according to this manufacturing method, the bonding between the first electrode and the second electrode can be more reliably improved.

In this method for manufacturing the semiconductor device, the layer thicknesses of the first organic insulating layer and the second organic insulating layer may be 2 μm to 10 μm, and the first organic insulating layer and the second organic insulating layer may be formed of a resin material having a glass transition temperature during curing of 200° C. to 400° C., and the resin material may have a linear expansion coefficient of 30 ppm/K to 100 ppm/K. In this case, in the hybrid bonding method using the organic insulating layer, the bonding between the electrodes can be more reliably improved.

In this method for manufacturing the semiconductor device, it is preferable that the resin material contained in the first organic insulating layer and the second organic insulating layer contain bismaleimide, polyimide, a polyimide precursor, polyamideimide, benzocyclobutene (BCB), polybenzoxazole (PBO), or a PBO precursor. In this case, even if the heating temperature increases at the time of bonding the first electrode and the second electrode in the hybrid bonding method, it is possible to prevent the first organic insulating layer and the insulating layer portion (second organic insulating layer) from hindering the bonding between the first electrode and the second electrode by softening or the like.

In this method for manufacturing the semiconductor device, at least one of the first protrusion amount or the second protrusion amount may be a protrusion amount of 50% to 100% of the protrusion amount ΔL. According to the study by the present inventors, since at least one (preferably both) of the first protrusion amount or the second protrusion amount is a protrusion amount within 50% to 100% of the protrusion amount ΔL, the organic insulating layers can be more reliably bonded to each other, the electrodes can be more reliably bonded to each other, and both the organic insulating layers and the electrodes can be more reliably bonded to each other.

In this method for manufacturing the semiconductor device, the bonding may include performing temporary pressure-bonding to bond the first organic insulating layer and the insulating layer portion to each other, and performing final pressure-bonding to bond the first electrode and the second electrode to each other. When the heating temperature at the time of performing the temporary pressure-bonding is set to the first heating temperature and the heating temperature at the time of performing the final pressure-bonding is set to the second heating temperature. At least one of the first protrusion amount or the second protrusion amount is preferably a protrusion amount within 130% of both the protrusion amount ΔL at the first heating temperature and the protrusion amount ΔL at the second heating temperature. In this case, the organic insulating layers are more reliably bonded to each other, the electrodes are more reliably bonded to each other, and both the organic insulating layers and the electrodes can be more reliably bonded to each other. In particular, in a case where the first heating temperature and the second heating temperature are different from each other, since the protrusion amount is within 130% of the protrusion amount ΔL in Formula (1) above in both the temporary pressure-bonding and the final pressure-bonding, it is possible to more reliably bond the organic insulating layers to each other in the temporary pressure-bonding, more reliably bond the electrodes to each other in the final pressure-bonding, and more reliably achieve the bonding of both.

In this method for manufacturing the semiconductor device, in the bonding, the temperature at which the first semiconductor substrate and the semiconductor chip are heated may be 230° C. to 280° C. In this case, it is possible to prevent the organic insulating layer from being excessively melted and having fluidity, and thus it is possible to suppress occurrence of deviation in bonding between the organic insulating layers or between the electrodes.

In this method for manufacturing the semiconductor device, in the bonding, the pressure at the time of pressurizing the first semiconductor substrate and the semiconductor chip may be 2.5 MPa or more. In this case, the electrodes can be bonded more reliably. In a case where the temperature at which the first semiconductor substrate and the semiconductor chip are heated is 230° C. to 280° C., even if the pressure is applied at such a high pressure (2.5 MPa or more), the deviation hardly occurs in the bonding between the organic insulating layers or the electrodes.

A method for manufacturing a semiconductor device according to another aspect of the present disclosure includes, preparing a first semiconductor substrate including a first substrate main body, and a first organic insulating layer and a first electrode which are provided on a surface of the first substrate main body; preparing a second semiconductor substrate including a second substrate main body, and a second organic insulating layer and a plurality of second electrodes which are provided on a surface of the second substrate main body; polishing surfaces of the first organic insulating layer and the first electrode which are disposed on the surface side of the first semiconductor substrate; polishing surfaces of the second organic insulating layer and the second electrode which are disposed on the surface side of the second semiconductor substrate, singulating the polished second semiconductor substrate into segments to obtain a plurality of semiconductor chips each including an insulating layer portion corresponding to the second organic insulating layer and at least one second electrode; aligning the second electrode of at least one semiconductor chip among the plurality of semiconductor chips with respect to the first electrode of the first semiconductor substrate; and bonding the first organic insulating layer and the insulating layer portion to each other, and bonding the first electrode and the second electrode to each other, by heating and pressurizing the first semiconductor substrate and the semiconductor chip. In this method for manufacturing the semiconductor device, when a semiconductor chip is bonded to the first semiconductor substrate by heating and pressurization, at least one of the first step difference amount between the first electrode and the first organic insulating layer or the second step difference amount between a second electrode and a second organic insulating layer is 10 nm or less.

In this method for manufacturing the semiconductor device according to other aspect, when a semiconductor chip is bonded to the first semiconductor substrate by heating and pressurization, at least one of the first step difference amount between the first electrode and the first organic insulating layer or the second step difference amount between a second electrode and a second organic insulating layer is 10 nm or less. In this case, the organic insulating layer is set in advance not to hinder the bonding between the electrodes even if the organic insulating layer is heated and expanded more than the electrodes. According to this manufacturing method, the bonding between the first electrode and the second electrode can be improved. Note that various aspects of the above-described method for manufacturing a semiconductor device may be applied individually or in combination to the method for manufacturing a semiconductor device according to the other aspect.

### Advantageous Effects of Invention

According to the present disclosure, a method for manufacturing a semiconductor device capable of improving bonding between electrodes in a hybrid bonding method using an organic insulating layer can be provided.

### BRIEF DESCRIPTION OF DRAWINGS

FIG. 1 is a cross-sectional view schematically illustrating an example of a semiconductor device (CoW) produced by a method for manufacturing a semiconductor device according to an embodiment of the present disclosure.

FIGS. 2A to 2F are schematic cross-sectional views sequentially illustrating a method for manufacturing the semiconductor device illustrated in FIG. 1.

FIGS. 3A to 3D are schematic cross-sectional views sequentially illustrating a method for manufacturing the semiconductor device illustrated in FIG. 1, and illustrate manufacturing steps after the steps illustrated in FIGS. 2A to 2F.

FIGS. 4A and 4B is views each illustrating a relationship between a height of an electrode and a height of an organic insulating layer in the method for manufacturing the semiconductor device illustrated in FIGS. 2A to 2F and FIGS. 3A to 3D. FIG. 4A illustrates a state when the electrode and the organic insulating layer are polished (before heating), and FIG. 4B illustrates a state when the electrode and the organic insulating layer are bonded (during heating).

FIG. 5 is a diagram illustrating a relationship between a protrusion amount of an electrode and a crimping yield in examples.

FIG. 6 is an observation cross-sectional photograph illustrating a degree of bonding to an electrode when hybrid bonding is performed using a protrusion amount (Cu protrusion amount) of two types of electrodes and two types of organic insulating materials.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description is omitted. Unless otherwise specified, positional relationships such as up, down, left, and right is based on the positional relationships illustrated in the drawings. The use of the terms “left”, “right”, “front”, “back”, “up”, “down”, “above”, “below”, and the like in the description of this specification and claims is intended for description and is not necessarily meant to indicate a permanent relative position thereof. The dimensional ratios in the drawings are not limited to the illustrated ratios.

In the present specification, the term “layer” includes a structure having a partially formed shape in addition to a structure having a shape formed on the entire surface when observed as a plan view. In the present specification, the term “step” includes not only an independent step but also a step that cannot be clearly distinguished from other step(s) as long as an intended action of the step is achieved. A numerical range indicated using “to” indicates a range including numerical values described before and after “to” as a minimum value and a maximum value, respectively.

### (Configuration of Semiconductor Device)

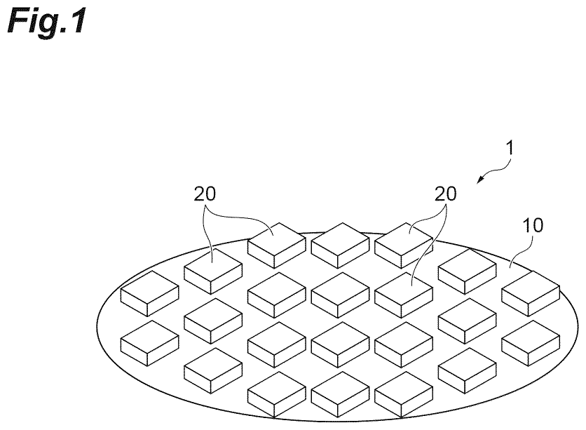

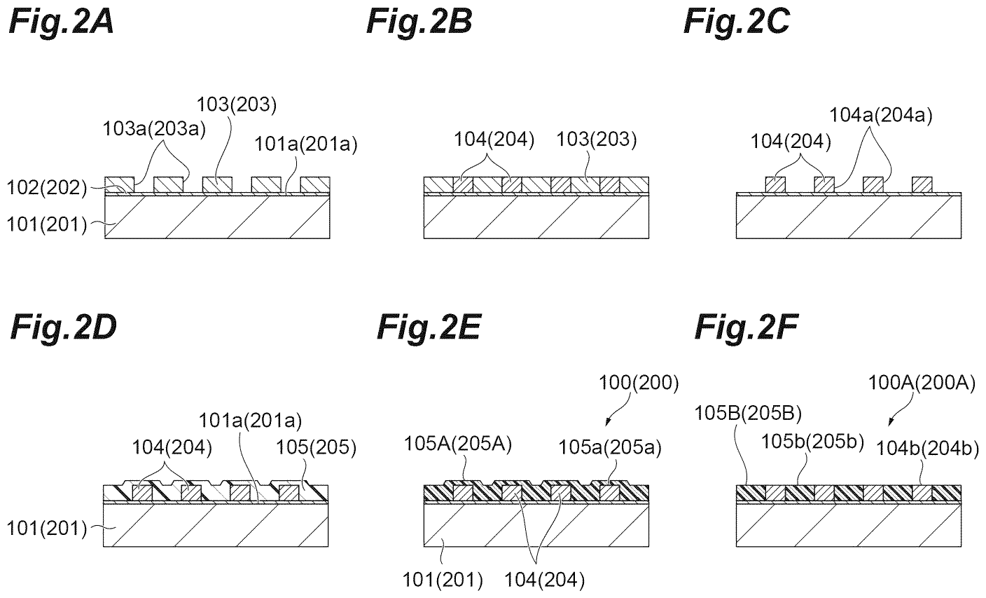

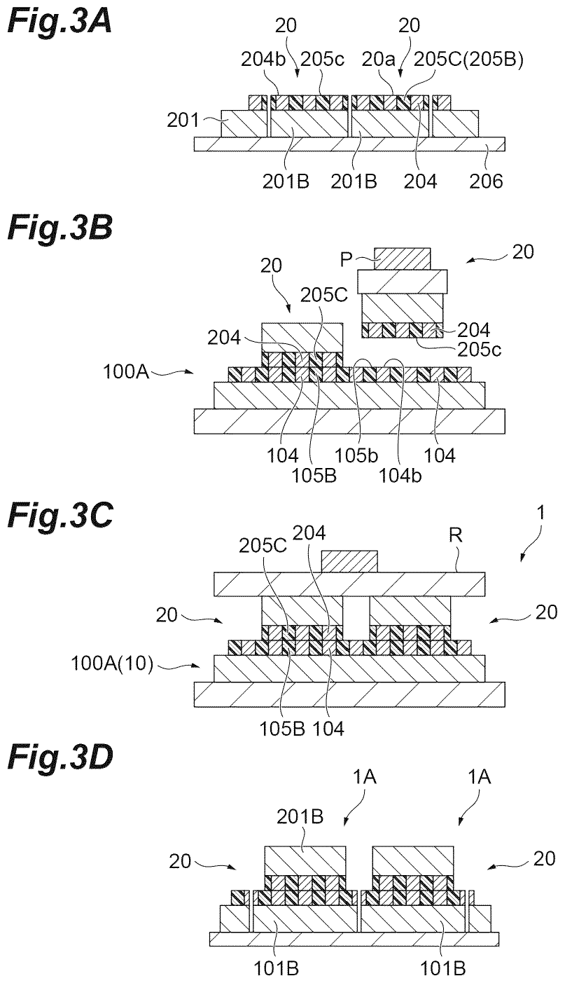

FIG. 1 is a cross-sectional view schematically illustrating an example of a semiconductor device manufactured by a method for manufacturing a semiconductor device according to an embodiment. As illustrated in FIG. 1, a semiconductor device 1 is, for example, an example of a semiconductor package, includes a first semiconductor substrate 10 and a plurality of semiconductor chips 20, and has a chip-on-wafer (CoW) structure. The plurality of semiconductor chips 20 are produced by dicing a second semiconductor substrate 200A (see FIG. 2F) to be described later into individual pieces. The plurality of semiconductor chips 20 are mounted on the first semiconductor substrate 10 to form a three-dimensional mounting structure. The first semiconductor substrate 10 may be a substrate in which a plurality of semiconductor chips such as a large scale integrated circuit (LSI) chip or a complementary metal oxide semiconductor (CMOS) sensor are formed at locations corresponding to the respective semiconductor chips 20, for example, but is not limited thereto. Each semiconductor chip 20 may be, for example, a semiconductor chip such as an LSI or a memory, but is not limited thereto. The first semiconductor substrate 10 and the plurality of semiconductor chips 20 are finely bonded to each other by a hybrid bonding method using an organic insulating layer to be described later such that each terminal electrode and the organic insulating layer around the terminal electrode are firmly fixed and not misaligned. Note that the semiconductor device 1 may be further divided into individual semiconductor devices 1A including one semiconductor chip 20 further divided from the configuration illustrated in FIG. 1 and a substrate portion which is a part of the first semiconductor substrate 10 corresponding to the one semiconductor chip 20 (see FIG. 3D).

### (Method for Manufacturing Semiconductor Device)

Next, a method for manufacturing the semiconductor device 1 will be described with reference to FIGS. 2A to 2F and FIGS. 3A to 3D. FIGS. 2A to 2F are schematic cross-sectional views sequentially illustrating a method for manufacturing the semiconductor device illustrated in FIG. 1. FIGS. 3A to 3D are schematic cross-sectional views sequentially illustrating a method for manufacturing the semiconductor device illustrated in FIG. 1, and are schematic views illustrating steps performed after the steps illustrated in FIGS. 2A to 2F.

The semiconductor device 1 can be manufactured, for example, through the following steps (a) to (g).
(a) A step of preparing a first semiconductor substrate including a first substrate main body, and a first organic insulating layer and a first electrode which are provided on a surface of the first substrate main body.
(b) A step of preparing a second semiconductor substrate including a second substrate main body, and a second organic insulating layer and a plurality of second electrodes which are provided on a surface of the second substrate main body.
(c) A step of polishing surfaces of the first organic insulating layer and the first electrode disposed on the surface side of the first semiconductor substrate.
(d) A step of polishing surfaces of the second organic insulating layer and the second electrode disposed on the surface side of the second semiconductor substrate.
(e) A step of singulating the polished second semiconductor substrate to obtain a plurality of semiconductor chips each including an insulating layer portion corresponding to the second organic insulating layer and at least one second electrode.
(f) A step of aligning the second electrode of at least one semiconductor chip among the plurality of semiconductor chips with the first electrode of the first semiconductor substrate.
(g) A step of bonding the first organic insulating layer and the insulating layer portion to each other and bonding the first electrode and the second electrode to each other by heating and pressurizing the first semiconductor substrate and the semiconductor chip.

[Step (a)]

The step (a) is a step of preparing a first semiconductor substrate which is a silicon substrate on which an integrated circuit including semiconductor elements, wiring connecting the semiconductor elements, and the like is formed. In the step (a), as illustrated in FIG. 2A, a plating base layer 102 is formed on the surface 101a of a first substrate main body 101 made of silicon or the like, and a resist layer 103 having a plurality of openings 103a having a predetermined pattern is formed on the plating base layer 102 using a dry film resist (DFR). The plating base layer 102 is, for example, a Ti/Cu layer, and is exposed to the plurality of openings 103a. The plating base layer 102 may be formed of another material. When the resist layer 103 is formed, as illustrated in FIG. 2B, copper is deposited in each opening 103a by electroplating to form a first electrode 104. The first electrode 104 may be formed of a material other than copper. Thereafter, as illustrated in FIG. 2C, the resist layer 103 is removed. As a result, a gap 104a is formed between the plurality of first electrodes 104.

Subsequently, an organic insulating material to be used for the first insulating layer is prepared. The organic insulating material used here is, for example, polyimide (PI), and is a resin material having a glass transition temperature Tg after curing of 250° C. or higher and a linear expansion coefficient of 30 ppm/K to 100 ppm/K. The organic insulating material used for the first insulating layer may be another resin material having a glass transition temperature Tg after curing of 200° C. to 400° C. and a linear expansion coefficient of 30 ppm/K to 100 ppm/K. As the organic insulating material, for example, a polyimide precursor (e.g. a polyimide amic ester, or a polyamic acid), a polyamideimide, a bismaleimide, benzocyclobutene (BCB), polybenzoxazole (PBO), a PBO precursor, or the like can be used other than the polyimide. These organic insulating materials are soft materials having a lower elastic modulus than inorganic materials such as silicon oxide (SiO₂). By using such an organic material, when the organic insulating layers are bonded to each other in the step (g) to be described later, even if fine debris exists on the insulating layer, the debris is absorbed into the organic insulating layer to prevent bonding failure due to the debris, and the organic insulating layers can be reliably bonded to each other. The organic insulating material is prepared as a liquid or solvent-soluble material.

When the liquid organic insulating material is prepared, as illustrated in FIG. 2D, an organic insulating material 105 is applied onto the surface 101a of the first substrate main body 101 by spin coating. As a result, the organic insulating material 105 fills the gaps 104a between the first electrodes 104 and covers the entire plurality of first electrodes 104. Once the organic insulating material 105 is applied in this manner, the semi-finished product including the organic insulating material 105 is heated at a high temperature (e.g. 350° C. or higher) for a predetermined period of time (e.g. 2 hours) to cure the organic insulating material 105, as illustrated in FIG. 2E. As a result, the organic insulating material 105 is cured to form a first insulating layer 105A. Thus, the first semiconductor substrate 100 is formed.

[Step (b)]

The step (b) is a step similar to the step (a), and is a step of preparing a second semiconductor substrate which is a silicon substrate on which an integrated circuit including semiconductor elements, wiring connecting the semiconductor elements, and the like is formed. In the step (b), as illustrated in FIG. 2A, a plating base layer 202 is formed on the surface 201a of a second substrate main body 201 made of silicon or the like, and a resist layer 203 having a plurality of openings 203a having a predetermined pattern is formed on the plating base layer 202 using a dry film resist. When the resist layer 203 is formed, as illustrated in FIG. 2B, copper is deposited in each opening 203a by electroplating to form a second electrode 204. The second electrode 204 may be formed of a material other than copper. Thereafter, as illustrated in FIG. 2C, the resist layer 203 is removed. As a result, a gap 204a is formed between the plurality of second electrodes 204.

Subsequently, an organic insulating material to be used for the second insulating layer is prepared. The organic insulating material used here is, for example, polyimide, and is a resin material having a glass transition temperature Tg after curing of 250° C. or higher and a linear expansion coefficient of 30 ppm/K to 100 ppm/K. The organic insulating material used for the second insulating layer may be another resin material having a glass transition temperature Tg after curing of 200° C. to 400° C. and a linear expansion coefficient of 30 ppm/K to 100 ppm/K. The other organic insulating material used for the second insulating layer may be the same as the other organic insulating material used for the first insulating layer, and the description thereof will be omitted. When the liquid organic insulating material is prepared, as illustrated in FIG. 2D, an organic insulating material 205 is applied onto the surface 201a of the second substrate main body 201 by spin coating. As a result, the organic insulating material 205 fills the gaps 204a between the second electrodes 204 and covers the entire plurality of second electrodes 204. Once the organic insulating material 205 is applied in this manner, the semi-finished product including the organic insulating material 205 is heated at a high temperature (e.g. 350° C. or higher) for a predetermined period of time (e.g. 2 hours) to cure the organic insulating material 205, as illustrated in FIG. 2E. As a result, the organic insulating material 205 is cured to form a second insulating layer 205A. Thus, the second semiconductor substrate 200 is formed.

[Step (c)]

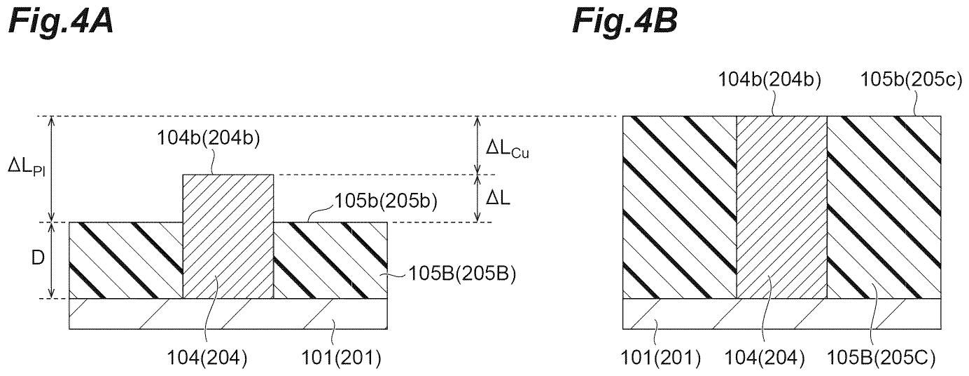

Subsequently, when the first semiconductor substrate 100 including the first insulating layer 105A made of the cured organic insulating material is formed, as illustrated in FIGS. 2E and 2F, a surface 105a of the first insulating layer 105A is polished using a chemical mechanical polishing (CMP) method. In the step (c), not only the first insulating layer 105A but also the tip end portion of each first electrode 104 is polished. In the step (c), as illustrated in FIG. 4A, a tip end 104b of the first electrode 104 is selectively polished by the CMP method to protrude from a surface 105b of a first insulating layer 105B. The protrusion amount (first protrusion amount) of the first electrode 104 from the surface 105b of the first insulating layer 105B is set to, for example, a protrusion amount ΔL based on Formula (2) below in consideration of expansion of the first insulating layer 105B due to heating at the time of bonding in a step (g) described later.

$$\begin{matrix}[ Formula 2 ] & \\ Δ L = \frac{D \times Δ T \times ( {α}_{PI} - {α}_{Cu} )}{1 + Δ T \times {α}_{Cu}} & ( 2 )\end{matrix}$$

In Formula (2) above, D is a layer thickness (before heating, room temperature, unit: (μm)) of the first insulating layer 105B, ΔT is a temperature difference between the temperature (room temperature) before bonding in the step (g) and the heating temperature at the time of bonding, α_{PI} is a linear expansion coefficient (10⁻⁶/K) of the material (PI: polyimide) constituting the first insulating layer 105A (corresponding to α1), and α_{Cu} is a linear expansion coefficient (10⁻⁶/K) of the material (copper) constituting the first electrode 104 (corresponding to α2). Here, the room temperature is 25° C.

The protrusion amount of the first electrode 104 from the surface 105b of the first insulating layer 105B may coincide with the protrusion amount ΔL calculated from Formula (2) above, but may be a protrusion amount within 130% of the protrusion amount ΔL, and is preferably a protrusion amount within 85% of the protrusion amount ΔL, and is preferably a protrusion amount within 60% of the protrusion amount ΔL. That is, the protrusion amount of the first electrode 104 is preferably smaller than the calculated protrusion amount ΔL. On the other hand, the protrusion amount of the first electrode 104 from the surface 105b of the first insulating layer 105B may be a protrusion amount of 20% or more of the protrusion amount ΔL calculated from Formula (2) above, and is preferably a protrusion amount of 40% or more of the protrusion amount ΔL. In addition, the protrusion amount of the first electrode 104 from the surface 105b of the first insulating layer 105B may be a protrusion amount of 50% to 100% of the protrusion amount ΔL calculated from Formula (2) above. Specifically, the protrusion amount of the first electrode 104 from the surface 105b of the first insulating layer 105B is preferably 40 nm to 100 nm, and more preferably 60 nm to 80 nm. The above-described selective polishing by CMP can be realized by changing the material configuration of the slurry or the polishing speed used in the CMP method.

By polishing by CMP, debris and the like on the surface of a first semiconductor substrate 100A are also removed. By the polishing in the step (c), the surface of the first semiconductor substrate 100A, that is, the surface 105b of the first insulating layer 105B and the surface of the tip end 104b of each first electrode 104, are polished to have a surface roughness Ra of 1 nm or less. By polishing the surfaces of the insulating layer and the electrodes in this manner, bonding is more reliably performed at the time of bonding in the step (g) described later. The surface roughness Ra used here is an arithmetic average roughness (Ra) defined in JIS B 0601-2001. The thickness of the first insulating layer 105B after being polished in this manner may be, for example, 2 μm or more and 10 μm or less.

[Step (d)]

Subsequently, when the second insulating layer 205A made of the cured organic insulating material is formed, as illustrated in FIGS. 2E and 2F, a surface 205a of the second insulating layer 205A is polished using the CMP method as in the step step (c). In the step (d), not only the second insulating layer 205A but also the tip end portion of each second electrode 204 is polished. In the step (d), for example, a tip end 204b of each second electrode 204 is selectively polished by the CMP method to protrude from a surface 205b of a second insulating layer 205B. Similarly to the protrusion amount of the first electrode 104, the protrusion amount (second protrusion amount) of the second electrode 204 from the surface 205b of the second insulating layer 205B is set to, for example, a protrusion amount ΔL based on Formula (2) above in consideration of expansion of the second insulating layer 205B due to heating at the time of bonding in the step (g) described later. However, in a case where the protrusion amount of the second electrode 204 is calculated, in Formula (2) above, D is the layer thickness (before heating, room temperature) of the second insulating layer 205B, ΔT is the temperature difference between the temperature (room temperature) before bonding in the step (g) and the heating temperature at the time of bonding, up, is the linear expansion coefficient of the material (PI: polyimide) constituting the second insulating layer 205A, and α_{Cu} is the linear expansion coefficient of the material (copper) constituting the second electrode 204.

The protrusion amount of the second electrode 204 from the surface 205b of the second insulating layer 205B may coincide with the amount of protrusion ΔL calculated from Formula (2) above as in the case of the first electrode 104, but may be a protrusion amount within 130% of the protrusion amount ΔL, and is preferably a protrusion amount within 85% of the protrusion amount ΔL, and is preferably a protrusion amount within 60% of the protrusion amount ΔL. That is, the protrusion amount of the second electrode 204 is preferably smaller than the calculated protrusion amount ΔL. On the other hand, the protrusion amount of the second electrode 204 from the surface 205b of the second insulating layer 205B may be a protrusion amount of 20% or more of the protrusion amount ΔL calculated from Formula (2) above, and is preferably a protrusion amount of 40% or more of the protrusion amount ΔL. In addition, the protrusion amount of the second electrode 204 from the surface 205b of the second insulating layer 205B may be a protrusion amount of 50% to 100% of the protrusion amount ΔL calculated from Formula (2) above. Specifically, the protrusion amount of the second electrode 204 from the surface 205b of the second insulating layer 205B is preferably 40 nm to 100 nm, and more preferably 60 nm to 80 nm. The protrusion amount of the second electrode 204 may be the same as or different from the protrusion amount of the first electrode 104. In a case where the protrusion amount of the second electrode 204 is different from the protrusion amount of the first electrode 104, it is preferable that the arithmetic average value of the protrusion amount ΔL1 of the first electrode 104 and the protrusion amount ΔL2 of the second electrode 204 is equal to the protrusion amount ΔL calculated from Formula (2) above or within the above range (for example, within 130% of ΔL). In addition, the second electrode 204 may have a shape recessed from the surface 205b of the second insulating layer 205B, and the first electrode 104 may have a shape protruding from the surface 105b of the first insulating layer 105B by the above-described amount, or may have the opposite configuration. In this case, the above-described arithmetic average value is calculated with the amount of the recessed electrode from the surface of the insulating layer as negative and the amount of the protruding electrode from the surface of the insulating layer as positive. Then, the arithmetic average value preferably matches the protrusion amount ΔL calculated from Formula (2) above or is within the above range (for example, within 130% of ΔL).

By polishing by CMP, debris and the like on the surface of a second semiconductor substrate 200A are also removed. By the polishing in the step (d), the surface of the second semiconductor substrate 200A, that is, the surface 205b of the second insulating layer 205B and the surface of the tip end 204b of each second electrode 204 are polished to have a surface roughness Ra of 1 nm or less. By polishing the surfaces of the insulating layer and the electrodes in this manner, bonding is more reliably performed at the time of bonding in the step (g) described later. The thickness of the second insulating layer 205A after being polished in this manner may be, for example, 2 μm or more and 10 μm or less.

[Step (e)]

Subsequently, when the polishing of the second semiconductor substrate 200 A is completed, in the step (e), the polished second semiconductor substrate 200A is divided into individual pieces, and a plurality of semiconductor chips 20 each including an insulating layer portion 205C corresponding to the second insulating layer 205B and at least one second electrode 204 are acquired. In the step (e), as illustrated in FIG. 3A, the second semiconductor substrate 200 is disposed on a dicing tape 206, and is divided into a plurality of semiconductor chips 20 by cutting means such as dicing from the second insulating layer 205B toward the second substrate main body 201. When the second semiconductor substrate 200A is diced, the second insulating layer 205B may be coated with a protective material or the like and then divided into individual pieces. By the step (e), the second insulating layer 205B of the second semiconductor substrate 200A is divided into insulating layer portions 205C corresponding to the respective semiconductor chips 20 as illustrated in FIG. 3A. Similarly, the second substrate main body 201 is divided into corresponding substrate portions 201B. As a dicing method for dividing the second semiconductor substrate 200A into individual pieces, for example, plasma dicing, stealth dicing, or laser dicing can be used.

[Step (f)]

Subsequently, when the second semiconductor substrate 200A is divided into individual pieces to form the plurality of semiconductor chips 20, as illustrated in FIG. 3B, the second electrode 204 of each semiconductor chip 20 is aligned with the first electrode 104 of the first semiconductor substrate 100A. In the step (f), the semiconductor chip 20 is picked up using a bonding pad P, and the second electrode 204 is aligned with the first electrode 104.

[Step (g)]

Subsequently, when the second electrode 204 of the semiconductor chip 20 is positioned with respect to the first electrode 104 of the first semiconductor substrate 100A, as illustrated in FIG. 3C, the first semiconductor substrate 100A and the semiconductor chip 20 are heated to a predetermined high temperature, for example, 200° C. to 350° C., and the semiconductor chip 20 is pressed against the first semiconductor substrate 100A at a predetermined pressure (e.g. 0.8 MPa). This pressing process is continued for about one hour using a pressing member R, for example. The heating described above is maintained during this pressing process. During this heat treatment, in the first semiconductor substrate 100A, as illustrated in FIG. 4B, the first insulating layer 105B is thermally expanded (the first electrode 104 is also thermally expanded), and the surface 105b of the first insulating layer 105B substantially coincides with the surface 104b of the first electrode 104. More specifically, the step difference amount (first step difference amount) between the first electrode 104 and the first insulating layer 105B is 10 nm or less. The step difference amount mentioned here is a recess amount in a case where the surface 104b of the first electrode 104 is recessed from the surface 105b of the first insulating layer 105B, and means a protrusion amount in a case where the surface 104b of the first electrode 104 protrudes from the surface 105b of the first insulating layer 105B. Similarly, at the time of the heat treatment, also in the semiconductor chip 20, as illustrated in FIG. 4B, the insulating layer portion 205C is thermally expanded (the second electrode 204 is also thermally expanded), and the surface 205c of the insulating layer portion 205C substantially coincides with the surface 204b of the second electrode 204. More specifically, the step difference amount (second step difference amount) between the second electrode 204 and the insulating layer portion 205C is 10 nm or less. The step difference amount mentioned here is the recess amount in a case where the surface 204b of the second electrode 204 is recessed from the surface 205c of the insulating layer portion 205C, and means the protrusion amount in a case where the surface 204b of the second electrode 204 protrudes from the surface 205c of the insulating layer portion 205C.

As described above, in the method for manufacturing the semiconductor device according to the present embodiment, the hybrid bonding is performed in a state where the surface 104b of the first electrode 104 and the surface 105b of the first insulating layer 105B substantially coincide with each other and the surface 204b of the second electrode 204 and the surface 205c of the insulating layer portion 205C substantially coincide with each other at the time of heating. By performing hybrid bonding in such a state, when the first insulating layer 105B of the first semiconductor substrate 100A and the insulating layer portion 205C of the semiconductor chip 20 are bonded, the first electrode 104 of the first semiconductor substrate 100 and the second electrode 204 of the semiconductor chip 20 can be more reliably abutted and bonded. Note that the bonding of the insulating layers and the bonding of the electrodes may be performed simultaneously, or after the insulating layers are bonded to each other, pressing may be further advanced to bond the electrodes to each other. By such bonding, the semiconductor device 1 illustrated in FIG. 1 is obtained.

In a case where the electrodes are bonded to each other by further pressing after the insulating layers are bonded to each other, in the step (g), a step of performing temporary pressure-bonding to bond the first insulating layer 105B and the insulating layer portion 205C to each other and a step of performing final pressure-bonding to bond the first electrode 104 and the second electrode 204 to each other are performed. In this bonding method, as described above, it is preferable that the surface 105b of the first insulating layer 105B substantially coincides with the surface 104b of the first electrode 104 (for example, the step difference amount between the first electrode 104 and the first insulating layer 105B is 10 nm or less), and the surface 205b of the second insulating layer 205B substantially coincides with the surface 204b of the second electrode 204 (for example, the step difference amount between the second electrode 204 and the second insulating layer 205B is 10 nm or less) in both the temporary pressure-bonding and the final pressure-bonding stages. Therefore, in the steps (c) and (d) of performing polishing, the protrusion amount of the first electrode 104 from the surface 105b of the first insulating layer 105B and the protrusion amount of the second electrode 204 from the surface 205b of the second insulating layer 205B are preferably in the above-described ranges even in a case where each of the temperature (first temperature) at the time of temporary pressure-bonding and the temperature (second temperature) at the time of final pressure-bonding is applied to Formula (2) described above.

That is, the protrusion amount of the first electrode 104 and the second electrode 204 before heating is preferably a protrusion amount within 130% of each protrusion amount ΔL calculated by applying each of the temporary pressure-bonding temperature and the final pressure-bonding temperature to Formula (2), preferably a protrusion amount within 85% of each protrusion amount ΔL, and preferably a protrusion amount within 60% of each protrusion amount ΔL. Similarly, the protrusion amounts of the first electrode 104 and the second electrode 204 before heating may be a protrusion amount of 20% or more with respect to each protrusion amount ΔL calculated by applying each of the temporary pressure-bonding temperature and the final pressure-bonding temperature to Formula (2), and is preferably a protrusion amount of 40% or more with respect to each protrusion amount ΔL. Similarly to the above, the protrusion amounts of the first electrode 104 and the second electrode 204 before heating may be a protrusion amount of 50% to 100% with respect to each protrusion amount ΔL calculated by applying each of the temporary pressure-bonding temperature and the final pressure-bonding temperature to Formula (2).

In a case where the temporary pressure-bonding and the final pressure-bonding are performed, the heating temperature and the pressurization pressure in the temporary pressure-bonding and the heating temperature and the pressurization pressure in the final pressure-bonding may be different from each other in both the temperature and the pressure, or may be partially different from each other. For example, the heating temperature in the temporary pressure-bonding may be 150° C. to 400° C., and the heating temperature in the final pressure-bonding may be 200° C. to 350° C. The pressurization pressure in the temporary pressure-bonding may be 1 MPa to 6 MPa, and the pressurization pressure in the final pressure-bonding may be 1 MPa to 20 MPa. According to studies by the present inventors, it has been found that, in both the temporary pressure-bonding and the final pressure-bonding, in a case where the heating temperature is set to 230° C. to 280° C. (e.g. 250° C.), even in a case where the pressurization pressure is set to 2.5 MPa or more, 3 MPa or more, 5 MPa or more, or 7 MPa or more, misalignment of the semiconductor chip 20 with respect to the first semiconductor substrate 100A hardly occurs. By increasing the pressurization pressure, in addition to shortening the bonding time and improving the bonding strength in the step (g), the first electrode 104 and the second electrode 204 (copper electrode) are elastically deformed and contracted by pressurization, so that the apparent ΔL of Formula (2) decreases. Therefore, even if the protrusion amount ΔL becomes larger than the above-described preferable range, connection can be appropriately performed, or the bonding temperature can be lowered.

As illustrated in FIG. 3D, the first semiconductor substrate 100 and the plurality of semiconductor chips 20 bonded to each other by hybrid bonding in this manner may be further divided into individual pieces. The semiconductor device 1A includes at least one semiconductor chip 20 and a substrate portion 201B corresponding to the semiconductor chip 20 in the first semiconductor substrate 100.

As described above, in the method for manufacturing the semiconductor device according to the present embodiment, before heating the first semiconductor substrate 100A and the semiconductor chip 20, one or both of the protrusion amount by which the first electrode 104 protrudes from the surface 105b of the first insulating layer 105B and the protrusion amount by which the second electrode 204 protrudes from the surface 205c of the insulating layer portion 205C are the protrusion amount within 130% of the protrusion amount ΔL represented by Formula (2) above. That is, the electrodes of the first electrode 104 and the second electrode 204 are set so protrude from the surface of the organic insulating layer by a predetermined amount at the stage prior to heating, and the organic insulating layer does not inhibit the bonding between the electrodes even if the organic insulating layer thermally expands at the time of heating. Therefore, according to this manufacturing method, even in a case where an organic insulating material is used for the insulating layer, the bonding between the first electrode 104 and the second electrode 204 can be improved.

In the method for manufacturing the semiconductor device according to the present embodiment, one or both of the protrusion amount of the first electrode 104 before heating and the protrusion amount of the second electrode 204 before heating may be 40 nm to 100 nm. In this case, even if the organic insulating layer expands at the time of heating, the organic insulating layer can be prevented from hindering abutting or bonding between the electrodes, and the bonding between the first electrode 104 and the second electrode 204 can be improved.

In the method for manufacturing the semiconductor device according to the present embodiment, one or both of the protrusion amount of the first electrode 104 before heating and the protrusion amount of the second electrode 204 before heating may be 60 nm to 80 nm. In this case, even if the organic insulating layer expands at the time of heating, the organic insulating layer can be prevented from hindering abutting or bonding between the electrodes, and the bonding between the first electrode 104 and the second electrode 204 can be improved.

In the method for manufacturing the semiconductor device according to the present embodiment, in the step of thermally bonding the semiconductor chip 20 to the first semiconductor substrate 100A, the step difference amount between the first electrode 104 and the first insulating layer 105B and the step difference amount between the second electrode 204 and the insulating layer portion 204C become, for example, 10 nm or less by heating. When the first semiconductor substrate 100A and the semiconductor chip 20 are heated and bonded, each organic insulating layer may be thermally expanded. However, by setting in advance such that the step between the electrode and the insulating layer at the time of expansion is 10 nm or less, it is possible to more reliably prevent the organic insulating layer from inhibiting abutting or bonding between the electrodes. According to this manufacturing method, the bonding between the first electrode 104 and the second electrode 204 can be more reliably improved.

In the method for manufacturing the semiconductor device according to the present embodiment, the resin material included in the first insulating layer 105B and the second insulating layer 205B may include bismaleimide, polyimide, a polyimide precursor, polyamideimide, benzocyclobutene (BCB), polybenzoxazole (PBO), or a PBO precursor. In this case, even when a high temperature is applied at the time of bonding the first electrode 104 and the second electrode 204 in the hybrid bonding method, it is possible to prevent the insulating layer portion 205C corresponding to the first insulating layer 105B and the second insulating layer 205B from being softened to hinder the bonding between the first electrode 104 and the second electrode 204.

In the method for manufacturing the semiconductor device according to the present embodiment, one or both of the protrusion amount of the first electrode 104 before heating and the protrusion amount of the second electrode 204 before heating may be a protrusion amount of 50% to 100% of the protrusion amount ΔL calculated from Formula (2) above. According to studies by the present inventors, it has been found that when the protrusion amount of each of the first electrode 104 and the second electrode 204 is a protrusion amount of 50% to 100% of the protrusion amount ΔL, the organic insulating layers can be more reliably bonded to each other, the electrodes can be more reliably bonded to each other, and both the electrodes can be more reliably bonded to each other.

In the method for manufacturing the semiconductor device according to the present embodiment, in the step of polishing the first semiconductor substrate 100, this polishing is performed so that the surface roughness Ra of each of the surfaces of the first insulating layer 105B and the first electrode 104 is 1 nm or less. In the step of polishing the second semiconductor substrate 200, this polishing is performed so that the surface roughness Ra of each of the surfaces of the second insulating layer 205B and the second electrode 204 is 1 nm or less. Since the surface roughness Ra of the organic insulating layers to be bonded is reduced by such polishing, when the semiconductor chip 20 is bonded to the first semiconductor substrate 100A, the bonding strength between the first insulating layer 105B and the insulating layer portion 205C of the semiconductor chip 20 can be increased. Similarly, the first electrode 104 and the second electrode 204 can be bonded more reliably, and the connection resistance between the electrodes can be reduced more reliably.

In the method for manufacturing the semiconductor device according to the present embodiment, the bonding step (g) may include a step of performing temporary pressure-bonding to bond the first insulating layer 105B and the insulating layer portion 205C to each other, and a step of performing final pressure-bonding to bond the first electrode 104 and the second electrode 204 to each other. When the heating temperature at the time of performing the temporary pressure-bonding is set to the first heating temperature and the heating temperature at the time of performing the final pressure-bonding is set to the second heating temperature, one or both of the protrusion amount of the first electrode 104 before heating and the protrusion amount of the second electrode 204 before heating are preferably a protrusion amount within 130% of both the protrusion amount ΔL at the first heating temperature and the protrusion amount ΔL at the second heating temperature. In this case, the organic insulating layers are more reliably bonded to each other, the electrodes are more reliably bonded to each other, and both the organic insulating layers and the electrodes can be more reliably bonded to each other. In particular, in a case where the first heating temperature and the second heating temperature are different from each other, since the protrusion amount is within 130% of the protrusion amount ΔL in Formula (2) above in both the temporary pressure-bonding and the final pressure-bonding, it is possible to more reliably bond the organic insulating layers to each other in the temporary pressure-bonding, more reliably bond the electrodes to each other in the final pressure-bonding, and more reliably achieve both the bonding.

### EXAMPLES

Hereinafter, the present invention will be described more specifically with reference to examples, but the present invention is not limited to examples.

First, a pair of test wafers corresponding to the first semiconductor substrate 100A and the second semiconductor substrate 200A (the plurality of semiconductor chips 20) described above was prepared. In this preparation, polyimide HD 4100 (trade name, produced by HD MicroSystems, Ltd.) and polyimide HD 7010 (trade name, produced by HD MicroSystems, Ltd.) were prepared as materials of the organic insulating layer used for the test wafer. The polyimide HD 4100 had a glass transition temperature of 290° C. after curing, and a linear expansion coefficient (CTE) of 100 ppm/K (10⁻⁶/° C.). The polyimide HD 7010 had a glass transition temperature of 267° C. after curing, and a linear expansion coefficient (CTE) of 75 ppm/K. The linear expansion coefficient of copper used for the electrode was 16.8 ppm/K (10⁻⁶/° C.).

Subsequently, as Example 1, a large number of first electrodes 104 which were copper pillars (Cu) having a size of 10 μm square and a height of 6 μm were produced on the first substrate main body 101 which is a silicon substrate by a semi additive step by the method illustrated in FIGS. 2A to 2F. Thereafter, the above-described polyimide HD 4100 was spin-coated on the first substrate main body 101 to cover the first electrodes 104, and baked at 375° C. for 2 hours in a nitrogen atmosphere to be cured. Thereafter, the surfaces of the first electrodes 104 and the cured product of polyimide HD 4100 (corresponding to the first insulating layer 105A) were polished by the CMP method. Thus, the first semiconductor substrate 100A was produced. In addition, the second semiconductor substrate 200A was produced by a similar method. At the time of this polishing, the protrusion amount of each first electrode 104 from the surface 105b of the first insulating layer 105B and the protrusion amount of each second electrode 204 from the surface 205b of the second insulating layer 205B were 46.7 nm. The thickness D of each insulating layer was 3.9 μm.

The surface roughness Ra of each of the surfaces of the first semiconductor substrate 100A and the second semiconductor substrate 200A polished by the CMP was 0.667 nm. The surface roughness Ra of the surface of the organic insulating layer was 0.375 nm. The surface roughness Ra was measured using a scanning probe microscope SPI 4000 (trade name, produced by Hitachi High-Tech Corporation) according to the method for measuring the arithmetic mean roughness (Ra) defined in JIS B 0601-2001.

Subsequently, one of the first test wafers corresponding to the second semiconductor substrate 200A was divided into a plurality of semiconductor chips by using a blade dicer DFD-6362 (trade name, produced by DISCO Corporation). The size of the individual chips was 5 mm×5 mm.

Subsequently, the individual 18 semiconductor chips (corresponding to the semiconductor chips 20) were subjected to electrode alignment with respect to the other of the first test wafer (corresponding to the first semiconductor substrate 100A), and then pressed against each other and heated at 300° C. for 2 hours. The temperature difference before and after heating was 275° C. The pressing force was 0.8 MP. Thereafter, it was confirmed whether crimping was performed, and the crimping yield was 100%. That is, it was confirmed that all the semiconductor chips were in close contact with the first semiconductor substrate 100A. Whether the crimping was possible was determined by touching the pressure-bonded semiconductor chip was touched with tweezers and confirming whether it dropped.

Next, as Example 2, the first semiconductor substrate 100A and the second semiconductor substrate 200A were produced by the same method as in Example 1. As a difference from Example 1, during CMP polishing, the protrusion amount of the first electrode 104 from the surface 105b of the first insulating layer 105B and the protrusion amount of the second electrode 204 from the surface 205b of the second insulating layer 205B were 78.8 nm. The thickness D of each insulating layer was 3.9 μm. The second semiconductor substrate 200A thus produced was divided into a plurality of semiconductor chips, and the individual 18 semiconductor chips were thermocompression-bonded to the first semiconductor substrate 100A. Conditions for thermocompression bonding were the same as those in Example 1, and for example, the compression bonding temperature was 300° C. (temperature difference before and after heating: 275° C.). When it was confirmed whether crimping was performed, the crimping yield was 17%.

Next, as Example 3, the first semiconductor substrate 100A and the second semiconductor substrate 200A were produced by the same method as in Example 1. As a difference from Example 1, during CMP polishing, the protrusion amount of the first electrode 104 from the surface 105b of the first insulating layer 105B and the protrusion amount of the second electrode 204 from the surface 205b of the second insulating layer 205B were 12.7 nm. The thickness D of each insulating layer was 4.0 μm. The second semiconductor substrate 200A thus produced was divided into a plurality of semiconductor chips, and the individual 90 semiconductor chips were thermocompression-bonded to the first semiconductor substrate 100A. The conditions for thermocompression bonding were the same as those in Example 1 except that the heating temperature was 350° C. (temperature difference before and after heating: 325° C.). When it was confirmed whether crimping was performed, the crimping yield was 100%.

Next, as Example 4, the first semiconductor substrate 100A and the second semiconductor substrate 200A were produced by the same method as in Example 1. As a difference from Example 1, during CMP polishing, the protrusion amount of the first electrode 104 from the surface 105b of the first insulating layer 105B and the protrusion amount of the second electrode 204 from the surface 205b of the second insulating layer 205B were 46.7 nm. The thickness D of each insulating layer was 3.9 μm. The second semiconductor substrate 200A thus produced was divided into a plurality of semiconductor chips, and the individual 18 semiconductor chips were thermocompression-bonded to the first semiconductor substrate 100A. The conditions for thermocompression bonding were the same as those in Example 1 except that the heating temperature was 350° C. (temperature difference before and after heating: 325° C.). When it was confirmed whether crimping was performed, the crimping yield was 100%.

Next, as Example 5, the first semiconductor substrate 100A and the second semiconductor substrate 200A were produced by the same method as in Example 1. As a difference from Example 1, during CMP polishing, the protrusion amount of the first electrode 104 from the surface 105b of the first insulating layer 105B and the protrusion amount of the second electrode 204 from the surface 205b of the second insulating layer 205B were 78.8 nm. The thickness D of each insulating layer was 3.9 μm. The second semiconductor substrate 200A thus produced was divided into a plurality of semiconductor chips, and the individual 18 semiconductor chips were thermocompression-bonded to the first semiconductor substrate 100A. The conditions for thermocompression bonding were the same as those in Example 1 except that the heating temperature was 350° C. (temperature difference before and after heating: 325° C.). When it was confirmed whether crimping was performed, the crimping yield was 83%.

Next, as Example 6, a first semiconductor substrate 100A and a second semiconductor substrate 200A were produced by the same method as in Example 1 except that the material used for the insulating layer was changed to polyimide HD7010. As a difference from Example 1, during CMP polishing, the protrusion amount of the first electrode 104 from the surface 105b of the first insulating layer 105B and the protrusion amount of the second electrode 204 from the surface 205b of the second insulating layer 205B were 13.0 nm. The thickness D of each insulating layer was 4.2 μm. The second semiconductor substrate 200A thus produced was divided into a plurality of semiconductor chips, and the individual 90 semiconductor chips were thermocompression-bonded to the first semiconductor substrate 100A. The conditions for thermocompression bonding were the same as those in Example 1 except that the heating temperature was 350° C. (temperature difference before and after heating: 325° C.). When it was confirmed whether crimping was performed, the crimping yield was 100%.

Next, as Example 7, the first semiconductor substrate 100A and the second semiconductor substrate 200A were produced by the same method as in Example 6. As a difference from Example 6, during CMP polishing, the protrusion amount of the first electrode 104 from the surface 105b of the first insulating layer 105B and the protrusion amount of the second electrode 204 from the surface 205b of the second insulating layer 205B were 91.5 nm. The thickness D of each insulating layer was 3.9 μm. The second semiconductor substrate 200A thus produced was divided into a plurality of semiconductor chips, and the individual 12 semiconductor chips were thermocompression-bonded to the first semiconductor substrate 100A. The conditions for thermocompression bonding were the same as those in Example 6, and for example, the heating temperature was 350° C. When it was confirmed whether crimping was performed, the crimping yield was 17%.

Next, as Example 8, the first semiconductor substrate 100A and the second semiconductor substrate 200A were produced by the same method as in Example 6. As a difference from Example 6, during CMP polishing, the protrusion amount of the first electrode 104 from the surface 105b of the first insulating layer 105B and the protrusion amount of the second electrode 204 from the surface 205b of the second insulating layer 205B were 52.7 nm. The thickness D of each insulating layer was 4.0 μm. The second semiconductor substrate 200A thus produced was divided into a plurality of semiconductor chips, and the individual 6 semiconductor chips were thermocompression-bonded to the first semiconductor substrate 100A. The conditions for thermocompression bonding were different from those in Example 6, and for example, the heating temperature was 300° C. (the temperature difference before and after heating was 275° C.). When it was confirmed whether crimping was performed, the crimping yield was 67%.

Next, as Comparative Example 1, the first semiconductor substrate 100A and the second semiconductor substrate 200A were produced by the same method as in Example 6. As a difference from Example 6, during CMP polishing, the protrusion amount of the first electrode 104 from the surface 105b of the first insulating layer 105B and the protrusion amount of the second electrode 204 from the surface 205b of the second insulating layer 205B were 91.5 nm. The thickness D of each insulating layer was 3.9 μm. The second semiconductor substrate 200A thus produced was divided into a plurality of semiconductor chips, and the individual 6 semiconductor chips were compression-bonded to the first semiconductor substrate 100A. The compression-bonding conditions were the same as those in Example 6 except that the heating temperature was 300° C. (the temperature difference before and after heating was 275° C.). When it was confirmed whether crimping was performed, the crimping yield was 0%.

The conditions in Examples 1 to 7 and Comparative Example 1 are summarized in the following Table 1.

TABLE 1

| | | | Protrusion | | Compression | | |
|---|---|---|---|---|---|---|---|
| | Types of | | amount of | Film | bonding | Temperature | |
| | insulating | CTE | electrode | thickness | temperature | difference | N |
| | film | (ppm/° C.) | (nm) | (μm) | (° C.) | (° C.) | number |
| Example 1 | HD4100 | 100 | 46.7 | 3.9 | 300 | 275 | 18 |
| Example 2 | HD4100 | 100 | 78.8 | 3.9 | 300 | 275 | 18 |
| Example 3 | HD4100 | 100 | 12.7 | 4.0 | 350 | 325 | 90 |
| Example 4 | HD4100 | 100 | 46.7 | 3.9 | 350 | 325 | 18 |
| Example 5 | HD4100 | 100 | 78.8 | 3.9 | 350 | 325 | 18 |
| Example 6 | HD7010 | 75 | 13.0 | 4.2 | 350 | 325 | 90 |
| Example 7 | HD7010 | 75 | 91.5 | 3.9 | 350 | 325 | 12 |
| Example 8 | HD7010 | 75 | 52.7 | 4.0 | 300 | 275 | 6 |
| Comparative | HD7010 | 75 | 91.5 | 3.9 | 300 | 275 | 6 |
| Example 1 | | | | | | | |

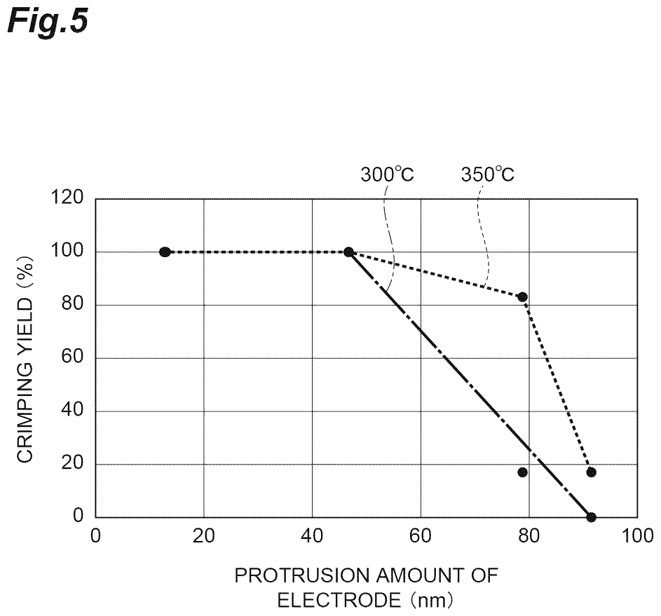

Table 2 below shows the relationship between the protrusion amount and the crimping yield in Examples 1 to 7 and a comparative example. Table 2 below shows the ΔL calculated value calculated based on Formula (2) and the deviation rate of the actual protrusion amount of the electrode from the ΔL calculated value. The deviation rate is a value (percentage) obtained by dividing the protrusion amount of the electrode by the ΔL calculated value. FIG. 5 illustrates a similar relationship.

TABLE 2

| | Protrusion amount | Crimping | ΔL | Deviation |
|---|---|---|---|---|
| | of electrode | yield | calculated | rate |
| | (nm) | (%) | value (nm) | (%) |
| Example 1 | 46.7 | 100 | 89.9 | 52% |
| Example 2 | 78.8 | 17 | 88.8 | 89% |
| Example 3 | 12.7 | 100 | 107.7 | 12% |
| Example 4 | 46.7 | 100 | 106.2 | 44% |
| Example 5 | 78.8 | 83 | 105.0 | 75% |
| Example 6 | 13.0 | 100 | 74.9 | 17% |
| Example 7 | 91.5 | 17 | 72.6 | 126% |
| Example 8 | 52.7 | 67 | 63.4 | 83% |
| Comparative | 91.5 | 0 | 61.4 | 149% |
| Example 1 | | | | |

### Example 1

As is clear from Table 2, in a case where the protrusion amount of the first electrode and the protrusion amount of the second electrode were within 130% of the ΔL calculated value, it could be confirmed that the organic insulating layers were in close contact with each other or the electrodes were in close contact with each other. In a case where the protrusion amount of the first electrode and the protrusion amount of the second electrode were within 85% of the ΔL calculated value, it could be confirmed that the close contact between the organic insulating layers or between the electrodes was more reliably achieved (yield was 60% or more). In a case where the protrusion amount of the first electrode and the protrusion amount of the second electrode were within 60% of the ΔL calculated value, it could be confirmed that the close contact between the organic insulating layers or between the electrodes was more reliably achieved (yield was 100%).

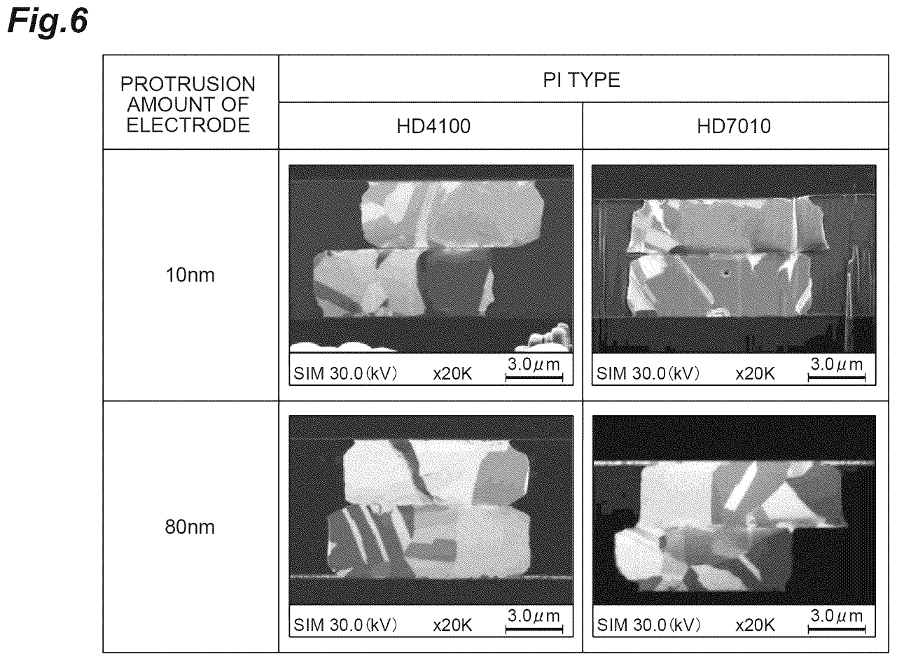

FIG. 6 illustrates adhesion states of electrodes in Example 3, Example 5, Example 6, and Example 7. More specifically, a photograph in which the protrusion amount of the electrode is 10 nm and the PI type is HD4100 corresponds to Example 3, a photograph in which the protrusion amount of the electrode is 80 nm and the PI type is HD4100 corresponds to Example 5, a photograph in which the protrusion amount of the electrode is 10 nm and the PI type is HD7010 corresponds to Example 6, and a photograph in which the protrusion amount of the electrode is 80 nm and the PI type is HD7010 corresponds to Example 7. In each example, the pressure-bonding temperature was 350° C. As illustrated in FIG. 6, it was confirmed that in Examples 5 and 7 in which the protrusion amount of the electrode was 80 nm, the joint surfaces of the electrodes were fused with each other, and a more suitable adhesion state was obtained, as compared with Examples 3 and 6 in which the protrusion amount of the electrode was 10 nm. That is, it was confirmed that when the deviation rate of ΔL with respect to the calculated value was 20% or more, the electrodes were in a more suitable adhesion state. In addition, focusing on Example 5, it has been found that when the deviation rate of the protrusion amount of the electrode with respect to the ΔL calculated value is 75%, that is, the deviation rate is within the range of 50% to 100%, the bonding strength between the electrodes is also improved in addition to the improvement of the crimping yield (mainly bonding between organic insulating layers). That is, it has been found that both improvement in bonding strength between organic insulating layers and improvement in bonding strength between electrodes can be achieved.

Next, the misalignment of the semiconductor chip at the time of bonding in the case where the pressure-bonding temperature was 300° C. and the case where the pressure-bonding temperature was 250° C. was evaluated. First, as Example 9, the first semiconductor substrate 100A and the second semiconductor substrate 200A were produced by the same method as in Example 8. As a difference from Example 8, at the time of CMP polishing, the protrusion amount of the first electrode 104 from the surface 105b of the first insulating layer 105B and the protrusion amount of the second electrode 204 from the surface 205b of the second insulating layer 205B were set to 60 nm. The second semiconductor substrate 200A thus produced was divided into a plurality of semiconductor chips, and the individual semiconductor chips were thermocompression-bonded to the first semiconductor substrate 100A. In this test, the electrodes are bonded in a daisy chain. The conditions for thermocompression bonding were different from those in Example 8, and the heating temperature was 250° C. (the temperature difference before and after heating was 225° C.). The pressurization pressure was 3 MPa, 5 MPa, and 7.5 MPa, respectively. In this bonding method, even in a case where the pressurization pressure was increased to 3 MPa or more (2.5 MPa or more) by lowering the heating temperature, displacement of the semiconductor chip hardly occurred. On the other hand, in a case where the test was performed in the same manner as in Example 9 and the heating temperature was set to 300° C., misalignment of the semiconductor chip occurred slightly (about 7 μm) when the pressurization pressure was set to 3 MPa, and misalignment of the semiconductor chip occurred (about 17 μm) when the pressurization pressure was set to 5 MPa.

As described above, according to the above example, it has been confirmed that the bonding between the electrodes can be improved by the hybrid bonding method using the organic insulating layer by causing the electrode to protrude from the surface of the organic insulating layer in advance in consideration of the expansion of the organic insulating layer.

### REFERENCE SIGNS LIST

1, 1A Semiconductor device
10 First semiconductor substrate
20 Semiconductor chip
100, 100A First semiconductor substrate
101 First substrate main body
101a surface
104 First electrode
104b Tip end
105 Organic insulating material
105A, 105B First insulating layer
105a, 105b Surface
200, 200A Second semiconductor substrate
201 Second substrate main body
201a surface
204 Second electrode
204b Tip end
205 Organic insulating material
205A, 205B Second insulating layer
205C Insulating layer portion
205c Surface

1. A method for manufacturing a semiconductor device, the method comprising:
preparing a first semiconductor substrate including a first substrate main body, and a first organic insulating layer and a first electrode which are provided on a surface of the first substrate main body;
preparing a second semiconductor substrate including a second substrate main body, and a second organic insulating layer and a plurality of second electrodes which are provided on a surface of the second substrate main body;
dividing the second semiconductor substrate into segments to obtain a plurality of semiconductor chips each including an insulating layer portion corresponding to the second organic insulating layer and at least one second electrode;
aligning the second electrode of at least one semiconductor chip among the plurality of semiconductor chips with respect to the first electrode of the first semiconductor substrate; and
bonding the first organic insulating layer and the insulating layer portion to each other, and bonding the first electrode and the second electrode to each other, by heating and pressurizing the first semiconductor substrate and the semiconductor chip,
wherein at least one of a first protrusion amount or a second protrusion amount is a protrusion amount within 130% of a protrusion amount ΔL represented by Formula (1) below before heating the first semiconductor substrate and the semiconductor chip, the first protrusion amount being an amount by which the first electrode protrudes from a surface of the first organic insulating layer and the second protrusion amount being an amount by which the second electrode protrudes from a surface of the second organic insulating layer or the insulating layer portion,
$$\begin{matrix}[ Formula 1 ] & \\ Δ L = \frac{D \times Δ T \times ( α 1 - α 2 )}{1 + Δ T \times α 2} & ( 1 )\end{matrix}$$
in Formula (1), D is a layer thickness of the first organic insulating layer or a layer thickness of the second organic insulating layer, ΔT is a temperature difference between the temperature before the bonding and a heating temperature at the time of the bonding, α1 is a linear expansion coefficient of the material forming the first organic insulating layer or the second organic insulating layer, and α2 is a linear expansion coefficient of the material forming the first electrode or the second electrode.

2. The method for manufacturing the semiconductor device according to claim 1, further comprising:
polishing surfaces of the first organic insulating layer and the first electrode which are disposed on the surface side of the first semiconductor substrate; and
polishing surfaces of the second organic insulating layer and the second electrode which are disposed on the surface side of the second semiconductor substrate,
wherein the corresponding polishing is performed such that at least one of the first protrusion amount and the second protrusion amount is a protrusion amount within 85% of the protrusion amount ΔL.

3. The method for manufacturing the semiconductor device according to claim 2,
wherein, in the polishing the first semiconductor substrate, the first semiconductor is polished such that a surface roughness Ra of each of the surfaces of the first organic insulating layer and the first electrode is 1 nm or less, and
wherein, in the polishing the second semiconductor substrate, the second semiconductor is polished such that the surface roughness Ra of each of the surfaces of the second organic insulating layer and the second electrode is 1 nm or less.

4. The method for manufacturing the semiconductor device according to claim 1,
wherein a protrusion amount of at least one of the first protrusion amount or the second protrusion amount is 40 nm to 100 nm.

5. The method for manufacturing the semiconductor device according to claim 1,
wherein the protrusion amounts of both the first protrusion amount and the second protrusion amount are 60 nm to 80 nm.

6. The method for manufacturing the semiconductor device according to claim 1,
wherein at least one of the first protrusion amount or the second protrusion amount is a protrusion amount of 20% or more of the protrusion amount ΔL before heating the first semiconductor substrate and the semiconductor chip.

7. The method for manufacturing the semiconductor device according to claim 1,
wherein both the first protrusion amount and the second protrusion amount are protrusion amounts within 60% of the protrusion amount ΔL before the first semiconductor substrate and the semiconductor chip are heated.

8. The method for manufacturing the semiconductor device according to claim 1,
wherein at least one of the first protrusion amount or the second protrusion amount is a protrusion amount of 50% to 100% of the protrusion amount ΔL.

9. The method for manufacturing the semiconductor device according to claim 1,
wherein the bonding includes
performing temporary pressure-bonding to bond the first organic insulating layer and the insulating layer portion to each other, and
performing final pressure-bonding to bond the first electrode and the second electrode to each other, and
wherein at least one of the first protrusion amount or the second protrusion amount is a protrusion amount within 130% of both the protrusion amount ΔL at a first heating temperature and the protrusion amount ΔL at a second heating temperature in a case where the heating temperature at the time of performing the temporary pressure-bonding is the first heating temperature and a heating temperature at the time of performing the final pressure-bonding is the second heating temperature.

10. The method for manufacturing the semiconductor device according to claim 1,
wherein, in the thermally bonding the semiconductor chip to the first semiconductor substrate, heating is performed such that at least one of a first step difference amount between the first electrode and the first organic insulating layer or a second step difference amount between the second electrode and the second organic insulating layer is 10 nm or less.

11. A method for manufacturing a semiconductor device, the method comprising:
preparing a first semiconductor substrate including a first substrate main body, and a first organic insulating layer and a first electrode which are provided on a surface of the first substrate main body;
preparing a second semiconductor substrate including a second substrate main body, and a second organic insulating layer and a plurality of second electrodes which are provided on a surface of the second substrate main body;
polishing surfaces of the first organic insulating layer and the first electrode which are disposed on the surface side of the first semiconductor substrate;
polishing surfaces of the second organic insulating layer and the second electrode which are disposed on the surface side of the second semiconductor substrate;
dividing the polished second semiconductor substrate into segments to obtain a plurality of semiconductor chips each including an insulating layer portion corresponding to the second organic insulating layer and at least one second electrode;
aligning the second electrode of at least one semiconductor chip among the plurality of semiconductor chips with respect to the first electrode of the first semiconductor substrate; and
bonding the first organic insulating layer and the insulating layer portion to each other, and bonding the first electrode and the second electrode to each other, by heating and pressurizing the first semiconductor substrate and the semiconductor chip,
wherein at least one of a first step difference amount between the first electrode and the first organic insulating layer or a second step difference amount between the second electrode and the second organic insulating layer is 10 nm or less when the semiconductor chip is bonded to the first semiconductor substrate by heating and pressurization.

12. The method for manufacturing the semiconductor device according to claim 1,
wherein the layer thicknesses of the first organic insulating layer and the second organic insulating layer are 2 μm to 10 μm, and
wherein the first organic insulating layer and the second organic insulating layer are formed of a resin material having a glass transition temperature during curing of 200° C. to 400° C., and the resin material has a linear expansion coefficient of 30 ppm/K to 100 ppm/K.

13. The method for manufacturing the semiconductor device according to claim 1,
wherein the resin material contained in the first organic insulating layer and the second organic insulating layer contains bismaleimide, polyimide, a polyimide precursor, polyamideimide, benzocyclobutene (BCB), polybenzoxazole (PBO), or a PBO precursor.

14. The method for manufacturing the semiconductor device according to claim 1,
wherein, in the bonding, a temperature at which the first semiconductor substrate and the semiconductor chip are heated is 230° C. to 280° C.

15. The method for manufacturing the semiconductor device according to claim 1,
wherein, in the bonding, a pressure when the first semiconductor substrate and the semiconductor chip are pressurized is 2.5 MPa or more.

16. The method for manufacturing the semiconductor device according to claim 11,
wherein the layer thicknesses of the first organic insulating layer and the second organic insulating layer are 2 μm to 10 μm, and
wherein the first organic insulating layer and the second organic insulating layer are formed of a resin material having a glass transition temperature during curing of 200° C. to 400° C., and the resin material has a linear expansion coefficient of 30 ppm/K to 100 ppm/K.

17. The method for manufacturing the semiconductor device according to claim 11,
wherein the resin material contained in the first organic insulating layer and the second organic insulating layer contains bismaleimide, polyimide, a polyimide precursor, polyamideimide, benzocyclobutene (BCB), polybenzoxazole (PBO), or a PBO precursor.

18. The method for manufacturing the semiconductor device according to claim 11,
wherein, in the bonding, a temperature at which the first semiconductor substrate and the semiconductor chip are heated is 230° C. to 280° C.

19. The method for manufacturing the semiconductor device according to claim 11,
wherein, in the bonding, a pressure when the first semiconductor substrate and the semiconductor chip are pressurized is 2.5 Pa or more.
